(19) United States
(12) Patent Application Publication
(10) Pub. No.: US 2025/0266304 A1
(43) Pub. Date: Aug. 21, 2025

(54) Semiconductor Wafer with Process Control Monitor Structures

(71) Applicant: Wolfspeed, Inc., Durham, NC (US)

(72) Inventors: Jared A. Langan, Apex, NC (US); Edward Robert Van Brunt, Cary, NC (US); Michael Vincent Pannone, Durham, NC (US); Charles D. Sturdevant, Greensboro, NC (US); Caleb Anton Lewis Rinderer, Raleigh, NC (US); Thomas Edgar Harrington, III, Durham, NC (US); In-Hwan Ji, Apex, NC (US); Lucile Caroline Teague Sheridan, Cary, NC (US)

(21) Appl. No.: 18/443,886

(22) Filed: Feb. 16, 2024

(51) Int. Cl. H01L 21/66; H01L 21/02; H01L 21/67; H01L 21/78

(52) U.S. Cl. CPC H01L 22/34; H01L 21/02378; H01L 21/67253; H01L 21/78

(57) ABSTRACT

A semiconductor wafer is provided. The semiconductor wafer includes a substrate. The semiconductor wafer further includes a first device structure on the substrate. The semiconductor wafer further includes a second device structure on the substrate. The semiconductor wafer further includes a gap region on the substrate between the first device structure and the second device structure. The semiconductor wafer further includes one or more process control monitor structures in the gap region. The semiconductor wafer further includes a first scribe line on a first side of the gap region and a second scribe line on a second side of the gap region.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or may be learned from the description, or may be learned through practice of the embodiments.

One example aspect of the present disclosure is directed to a semiconductor wafer. The semiconductor wafer includes a substrate. The semiconductor wafer further includes a first device structure on the substrate. The semiconductor wafer further includes a second device structure on the substrate. The semiconductor wafer further includes a gap region on the substrate between the first device structure and the second device structure. The semiconductor wafer further includes one or more process control monitor structures in the gap region. The semiconductor wafer further includes a first scribe line on a first side of the gap region and a second scribe line on a second side of the gap region.

Another example aspect of the present disclosure is directed to a method for processing a semiconductor wafer. The method includes providing a semiconductor wafer comprising a substrate, a first device structure on the substrate, a second device structure on the substrate, a gap region on the substrate between the first device structure and the second device structure, and one or more process control monitor structures on the gap region. The method further includes dicing the semiconductor wafer along a first scribe line on a first side of the gap region. The method further includes dicing the semiconductor wafer along a second scribe line on a second side of the gap region.

Another example aspect of the present disclosure is directed to a semiconductor wafer. The semiconductor wafer includes a substrate. The semiconductor wafer further includes a plurality of semiconductor device structures on the substrate divided by a plurality of scribe lines for separating the semiconductor device structures. The semiconductor wafer further includes a gap region extending between a plurality of the semiconductor devices, the gap region having a width that is greater than one of the scribe lines and less than the width of one of the semiconductor device structures. The semiconductor wafer further includes at least one process control monitor structure within the gap region.

Another example aspect of the present disclosure is directed to a semiconductor wafer. The semiconductor wafer includes a substrate. The semiconductor wafer further includes a plurality of device structures on the substrate, the plurality of device structures in a plurality of device arrays. Each device array comprises a process control monitor unit having one or more process control monitor structures. An area of the process control monitor unit for each device array is less than an area of one of the plurality of device structures in the device array.

Another example aspect of the present disclosure is directed to a semiconductor wafer. The semiconductor wafer includes a substrate. The semiconductor wafer further includes a plurality of device structures on the substrate. The semiconductor wafer further includes a plurality of process control monitor structures on the substrate, the plurality of process control monitor structures distributed on the substrate such that all of the plurality of device structures on the substrate are within about 20 mm of at least one of the plurality of process control monitor structures. A total process control monitor area occupied by all the process monitor control structures is less than about 3% of a surface area of the semiconductor wafer.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example semiconductor wafer having a plurality of process control monitor (PCM) structures;

FIGS. 2A and 2B depicts simplified views of semiconductor device arrays having a plurality of PCM structures;

FIG. 3 depicts an example semiconductor wafer according to example embodiments of the present disclosure;

FIG. 4 depicts an example semiconductor wafer according to example embodiments of the present disclosure;

FIG. 5 depicts an example device array according to example embodiments of the present disclosure;

FIG. 6 depicts a close-up view of an example device array according to example embodiments of the present disclosure;

FIG. 7 depicts an example semiconductor wafer according to example embodiments of the present disclosure; and

FIG. 8 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices may be fabricated using epitaxial layers formed on a substrate of a semiconductor wafer, such as a silicon carbide semiconductor wafer. A plurality of “unit cell” structures may be formed in the epitaxial layers, where each unit cell structure includes a transistor or other device. A large number of these unit cells may together form a semiconductor device structure. Metal layers may be formed on these unit cells to form contacts for the semiconductor (e.g., gate electrode, source electrode, drain electrode). The semiconductor wafer may be cut or diced along scribe lines between semiconductor device structures, such that each individual cut piece becomes a semiconductor die that is later packaged in a semiconductor device package (e.g., discrete semiconductor device package or a power module). A scribe line refers to a line where the semiconductor wafer may later be cut or diced (e.g., using a wire saw or a laser).

Process Control Monitoring (PCM) is a form of data collection for semiconductor fabrication. PCM uses PCM structures for process control and testing of semiconductor wafers and semiconductor devices on the semiconductor wafers during semiconductor device fabrication. Example PCM structures may be metrology structures, alignment structures, or electrical test structures.

While PCM has been utilized extensively in silicon fabrication, silicon carbide fabrication provides unique challenges and tradeoffs that are not present with pure silicon. For instance, during processing silicon wafers, PCM structures can be placed in scribe lines between semiconductor device structures. During the dicing process the PCM structures are obliterated with no impact to the function or reliability of silicon devices. However, dicing through PCM structures on silicon carbide-based semiconductor wafers causes significant contamination as debris from the materials used to form the PCM structures lands on device structures and the silicon carbide substrate, causing failure and/or degradation of the device structures. Further, cutting instruments (e.g., saws) used to cut through silicon carbide wafers can be severely damaged by materials used for PCM structures.

As a result, silicon carbide-based semiconductor device fabrication has typically used different methodologies from silicon fabrication for implementing PCM structures. For instance, many fabrication processes sacrifice an entire semiconductor device die region in the field array and instead populate the region with one or more PCM structures. Using such a strategy prevents dicing of the PCM structure, however, negatively impacts the amount of functional and sellable semiconductor die, reducing yield on the semiconductor wafer. Alternatively, some silicon carbide fabrication processes forgo PCM structure implementation. However, foregoing PCM means that there is no insight during processing of wafer and device health until the final test or back-end flow.

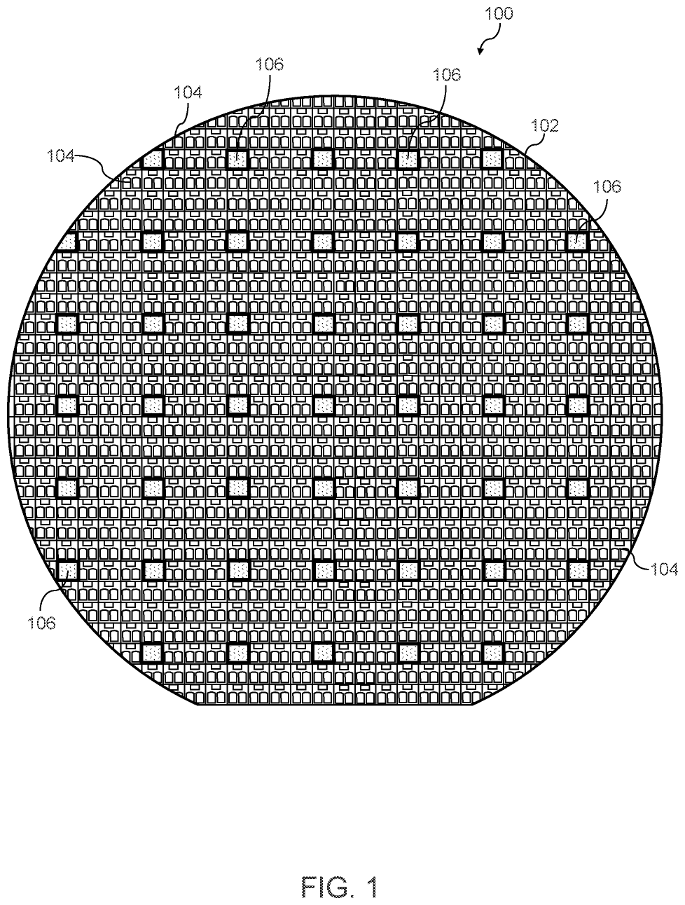

FIG. 1 depicts an example semiconductor wafer 100 according to such a method, where a semiconductor die region for a device structure has been used to accommodate a PCM structure. The semiconductor wafer 100 includes a substrate 102, a plurality of device structures 104, and a plurality of PCM regions 106. As shown in FIG. 1, the device structures 104 (e.g., eventual semiconductor die) may be arranged in a plurality of device arrays (e.g., 4×4 device arrays). Each device array may correspond, for instance, to a photolithography shot or reticle used during the semiconductor fabrication process.

The device structures 104 may be eventual semiconductor die once the semiconductor wafer is diced along scribe lines. The device structures 104 may be, for instance, silicon carbide MOSFETs, Schottky diodes, or other devices (e.g., Group III-nitride-based HEMTs). Each device structure 104 may be the same or may include different device structures. For instance, in some examples, the plurality of device structures 104 may include one or more first device structures of a first type (e.g., first die arrangement or layout) and one or more second device structures of a second type (e.g., second die arrangement or layout) that is different from the first type.

As shown in FIG. 1, the semiconductor wafer 100 includes a plurality of process control monitor (PCM) regions 106. A PCM region 106 refers to a region where one or more PCM structures may be located on the semiconductor wafer 100. A PCM structure may be, for instance, one or more of an alignment structure, a metrology structure, or an electrical test structure. In the example of FIG. 1, each PCM region 106 is the same size as a region or space used by a device structure 104 (e.g., a semiconductor die).

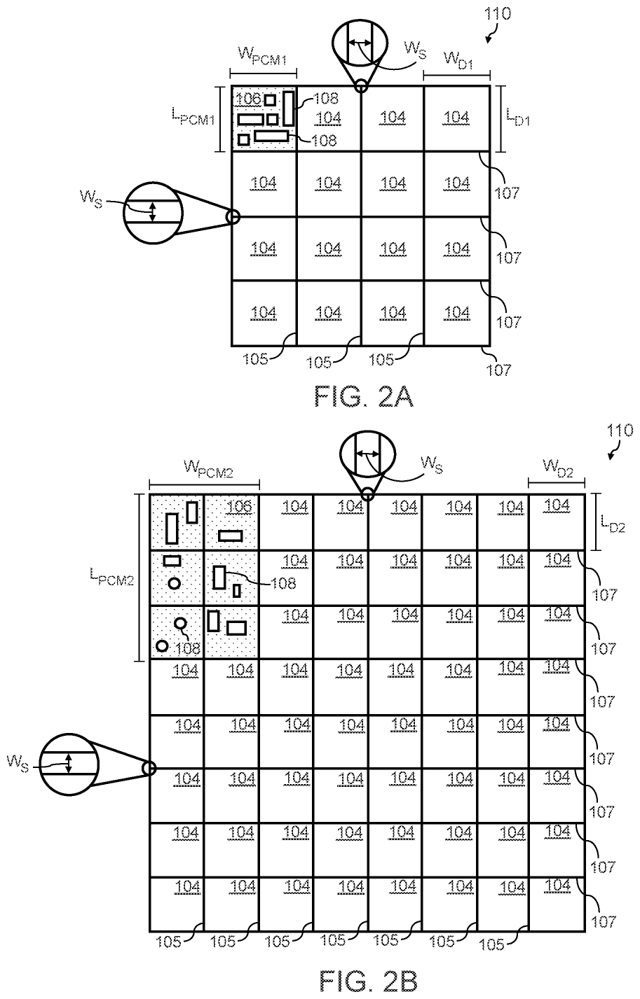

More particularly, FIG. 2A depicts a simplified view of one device array 110 (e.g., 4×4 array) of the semiconductor wafer 100. The device array 110 includes a plurality of device structures 104 (e.g., eventual semiconductor die). The semiconductor wafer 100 includes first scribe lines 105 running a first direction and second scribe lines 107 running in a second direction. The first direction may be generally perpendicular to the second direction. When the wafer 100 is cut or diced through the first scribe lines 105 and second scribe lines 107, the device structures 104 are separated into individual semiconductor die.

The first scribe lines 105 and the second scribe lines 107 may each have a width W_{S1}. The width W_{S1}, in some examples, may correspond to a width of a cutting tool (e.g., saw, laser) used to dice the semiconductor wafer 100. The first scribe lines 105 and the second scribe lines 107 may have any suitable width without deviating from the scope of the present disclosure.

As shown in FIG. 2A, the device array 110 includes a PCM region 106. The PCM region 106 is a space in the array that can accommodate PCM structures 108. The PCM structures 108 may include one or more metrology structures, alignment structures, and electrical test structures. In the example of FIG. 2A, the PCM region 106 corresponds to a region typically used by a semiconductor device structure 104 (e.g., eventual semiconductor die). For instance, the PCM region 106 has a length L_{PCM1} and a width W_{PCM1}. A device structure has a length L_{D1} and a width W_{D1}. The area of the PCM region 106 as defined by the length L_{PCM1} and width W_{PCM1} is the about the same as the area of the device region of a device structure 104 defined by L_{D1} and W_{D1}.

Another example is shown in FIG. 2B. In this example, the device array 110 includes an 8×8 array of smaller device structures 104. The semiconductor wafer 100 includes first scribe lines 105 running a first direction and second scribe lines 107 running in a second direction. The first direction may be generally perpendicular to the second direction. The first scribe lines 105 and the second scribe lines 107 may each have a width W_{S}. The width W_{S}, in some examples, may correspond to a width of a cutting tool (e.g., saw, laser) used to dice the semiconductor wafer 100. The first scribe lines 105 and the second scribe lines 107 may have any suitable width without deviating from the scope of the present disclosure.

As shown in FIG. 2B, the device array 110 includes a PCM region 106. The PCM region 106 is a space or region in the array that can accommodate PCM structures 108. The PCM structures 108 may include one or more metrology structures, alignment structures, and electrical test structures. In the example of FIG. 2B, the PCM structures 108 may not be able to fit into a space or region typically occupied by a single device structure 104. In that regard, the PCM region 106 of FIG. 2B corresponds to a space or region that is an integer multiple (e.g., 6×) of the area typically occupied by a single device structure 104. For instance, the PCM region 106 has a length L_{PCM2} and a width W_{PCM2}. A device structure has a length L_{D2} and a width W_{D2}. The area of the PCM region 106 as defined by the length L_{PCM2} and width W_{PCM2} is about six times the area of the device region of a device structure 104 defined by L_{D2} and W_{D2}.

In the example of FIG. 2B, the PCM region 106 extends across six semiconductor device regions. However, those of ordinary skill in the art, using the disclosures provided herein, will understand that the PCM region 106 may encompass more or fewer integer multiples of the device region.

Example aspects of the present disclosure are directed to semiconductor wafers that incorporate PCM structures onto silicon carbide semiconductor wafers without having to sacrifice individual semiconductor device structure regions. More particularly, aspects of the present disclosure are directed to including gap regions between scribe lines on a semiconductor wafer to accommodate PCM structures and other sacrificial structures on the semiconductor wafer.

The gap region refers to a space that runs parallel or perpendicular to one or more scribe lines on the semiconductor wafer but is not a path for cutting or dicing of the semiconductor wafer. As used herein, the collective region defined by the gap region and the first scribe line and the second scribe line on either side of the gap region is referred to as a “superstreet region.”

In some examples, the gap region does not include any semiconductor device structures. The PCM structures in the gap region may not overlap any scribe lines (e.g., scribe lines in any direction). In this way, the semiconductor wafer can be diced without destroying or damaging the PCM structures within the gap region.

Examples of the present disclosure provide technical effects and benefits. For example, by using superstreet regions in such a manner on a semiconductor wafer and by reducing PCM structure area, the resulting wafers and methods provide for an increased total number of device structures on the semiconductor wafer. For instance, use of superstreet regions allows for a larger area of semiconductor wafer real estate to be used for device structures. Further, use of the gap region between scribe lines as disclosed may reduce the need for the PCM structures to be cut during processing of the semiconductor wafer, which leads to fewer device structure failures and more usable device structures, increasing overall yield for the fabrication process. Also, use of the gap region between scribe lines as disclosed prevents destruction of cutting instruments, leading to manufacturing improvements as a result of reduced downtime to repair or replace cutting instruments. Further, an increased number of PCM structures can be included to generate more data to monitor the health of fabrication processes and systems. Improved loading effects on adjacent device structures (e.g., die) can also be realized. Additionally, a tighter alignment of PCM structures can be realized, which can increase data collection as well as increased uniformity of the device structures. Further, multiple PCM structures can be tested in parallel, increasing semiconductor wafer throughput and reducing the overall capital equipment footprint. In addition, the PCM structure may be placed on the semiconductor wafer at regular and/or irregular intervals as needed due to the flexibility of providing superstreets on the semiconductor wafer.

Examples of the present disclosure are discussed with reference to PCM structures in a gap region for purposes of illustration and discussion. Those of ordinary skill in the art, using the disclosures provided herein, will understand that other sacrificial or non-device structures may be located in the PCM region without deviating from the scope of the present disclosure.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

As used herein, the term “width” when used in conjunction with a region or space on a semiconductor wafer refers to the short dimension in a plane co-planar with or parallel to a major surface of the semiconductor wafer. The term “length” when used in conjunction with a region or space on a semiconductor wafer refers to the long dimension in a plane co-planar with or parallel to a major surface of the semiconductor wafer. The length and the width are generally perpendicular to one another. “Width” and “length” may be used interchangeable when referring to a region with equal dimensions (e.g., equal width and equal length).

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

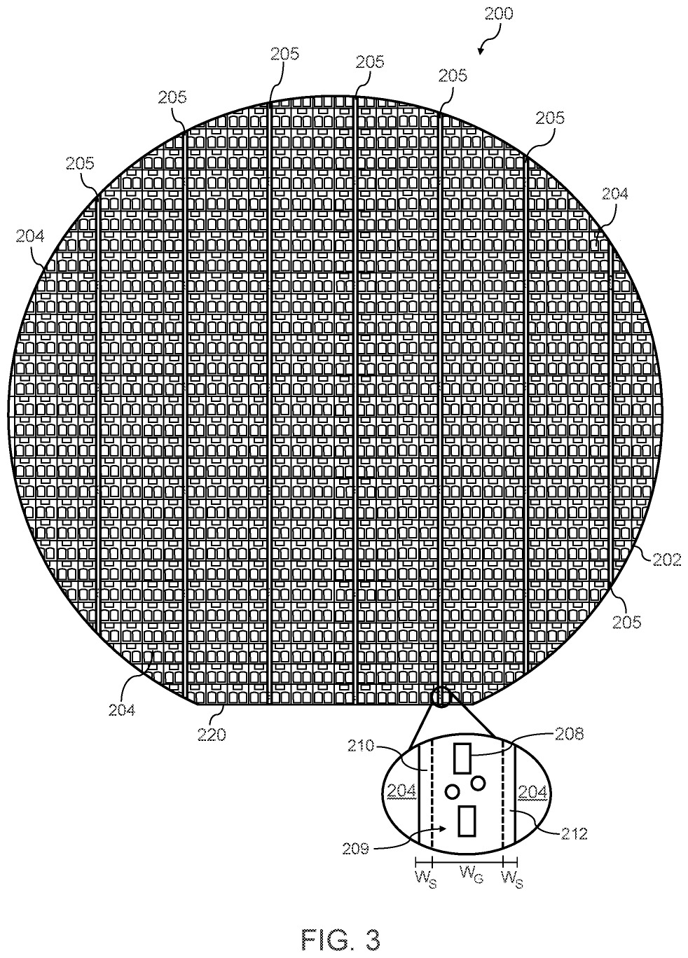

FIG. 3 depicts a semiconductor wafer 200 according to example embodiments of the present disclosure. FIG. 3 is intended to represent structures for identification and description and is not intended to represent the structures to physical scale. The semiconductor wafer 200 includes a substrate 202 and one or more device structures 204 on the substrate 202. The one or more device structures 204 may be divided by scribe lines (e.g., spaces between device structures 204) for dicing the semiconductor wafer 200 into individual semiconductor die. The device structures 204 may be, for instance, silicon carbide MOSFETs, Schottky diodes, or other devices (e.g., Group III-nitride-based HEMTs). The semiconductor wafer 200 includes at least one superstreet region 205 between certain of the device structures 204.

The semiconductor wafer 200 may have a diameter in a range of about 100 mm to about 300 mm. For instance, in some examples, the semiconductor wafer 200 may have a diameter of about 150 mm. In some examples, the semiconductor wafer 200 may have a diameter of about 200 mm.

The substrate 202 may be a semiconductor material. For instance, the substrate 202 may be a silicon substrate, a silicon carbide (SiC) substrate, a sapphire substrate, or other suitable substrate. In some embodiments, the substrate 202 may be a SiC substrate that may be, for example, the 4H polytype of SiC or may be the 3C, 6H, and 15R polytypes of SiC. The substrate 202 may be a High Purity Semi-Insulating (HPSI) substrate, available from Wolfspeed, Inc.

In some embodiments, the SiC bulk crystal of the substrate 202 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. In some examples, the substrate 202 may have a thickness in a range of, for instance, about 50 μm to about 300 μm, such as in range of about 75 μm to about 200 μm, such as about 100 μm.

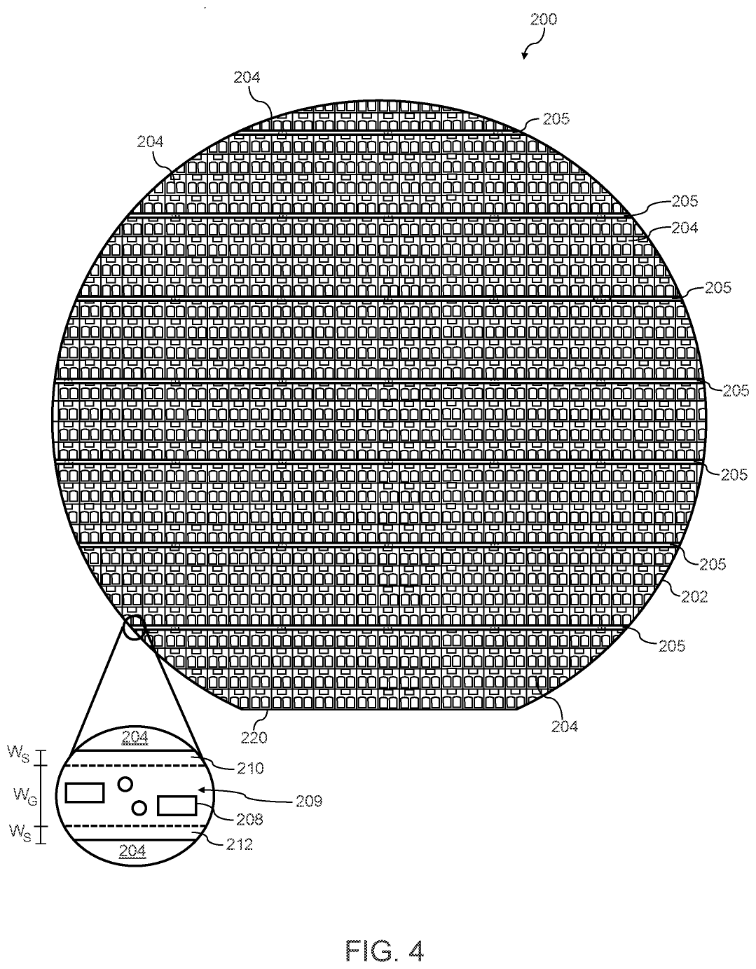

The substrate 202 can include a flat 220 (or a notch) associated with a crystal orientation of the semiconductor wafer 200. As shown in FIG. 2, the superstreet regions 205 are generally perpendicular to the flat 220 (or to the notch (e.g., the long dimension of the notch)). However, the superstreet regions 205 may have other orientations without deviating from the scope of the present disclosure. For instance, as shown in FIG. 4, the superstreet regions 205 are generally parallel to the flat 220 (or to the notch (e.g., the long dimension of the notch)). In some examples, the superstreet regions 205 may be angled (e.g., non-parallel and non-perpendicular) with respect to the flat 220. In some embodiments, the superstreet regions 205 may extend all the way across the semiconductor wafer 200. In some embodiments, the superstreet regions 205 extend only partially across the semiconductor wafer 200.

FIGS. 3 and 4 each provide a close-up view of a portion of a superstreet region 205 between device structures 204 according to example embodiments of the present disclosure. As shown, the superstreet region 205 includes a gap region 209. The gap region 209 is between two device structures 204. The gap region 209 is between a first scribe line 210 and a second scribe line 212. The gap region 209 is a linear gap region having a length extending in a direction that is generally parallel to the first scribe line 210 and the second scribe line 212. The gap region 209 is not intended for cutting or dicing of the wafer along its length. No semiconductor device structures 204 are located in the gap region 209.

According to examples of the present disclosure, the gap region 209 may have a width W_{G}. The first scribe line 210 and the second scribe line 212 may have a width W_{S}. The width W_{S} of the first scribe line 210 and the second scribe line 212 may correspond to a width of a cutting tool used to dice the semiconductor wafer 200 (e.g., saw, laser). The width W_{G} of the gap region is greater than the width W_{S} of the first scribe line 210 and the second scribe line 212. The combined width of the first scribe line 210, the second scribe line 212, and the gap region 209 may be the width of the superstreet 205.

As shown in FIGS. 3 and 4, one or more PCM structures 208 may be within the gap region 209. The one or more PCM structures 208 may include one or more alignment structures, metrology structures, and/or electrical test structures. The one or more PCM structures 208 may be located in the gap region 209 such that the PCM structures 208 do not overlap any scribe lines 210, 212 of the semiconductor wafer 200, irrespective of the direction of the scribe lines. In this way, the PCM structures 208 are not cut or diced during a dicing process for the semiconductor wafer 200.

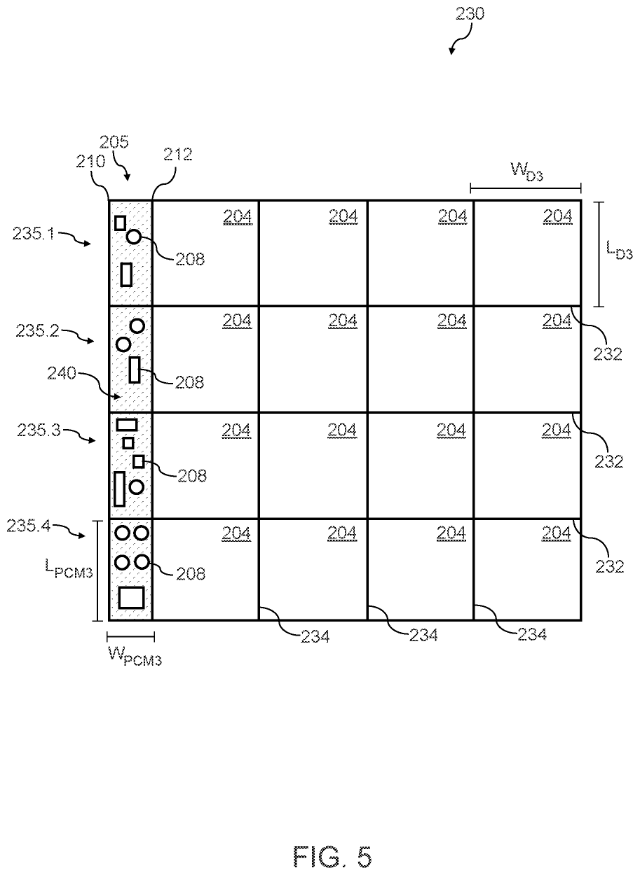

FIG. 5 depicts a close-up view of an example device array 230 that may be on the semiconductor wafer 200. The device array 230 may correspond to a photolithography shot or reticle. The device array 230 includes a 4×4 array in the example of FIG. 5. While a 4×4 device array is shown, it should be appreciated that the present disclosure is not so limited and that any array can be used without departing from the scope of the present disclosure. For instance, other device arrays may include 5×5, 6×6, 7×7, etc.

The device array 230 includes a plurality of semiconductor device structures 204. In some examples, each device structure 204 in the array 230 is the same. In some examples, the device array 230 may include different device structures 204. For instance, in some examples, the device array 230 may include one or more first device structures of a first type (e.g., first die arrangement or layout) and one or more second device structures of a second type (e.g., second die arrangement or layout) that is different from the first type.

Scribe lines 232 may run in a first direction and scribe lines 234 may run in a second direction. The semiconductor device structures 204 may be singulated into individual semiconductor die by dicing the device array 230 along the scribe lines 232 and the scribe lines 234.

As shown in FIG. 5, the device array 230 includes an associated superstreet 205. The superstreet 205 includes a gap region 209 between a first scribe line 210 and a second scribe line 212. The device array 230 includes a PCM region 240 indicated by the shading. In contrast to the device arrays illustrated in FIGS. 2A and 2B, the PCM region 240 is in the gap region 209 of the superstreet 205. The PCM region 240 accommodates a plurality of PCM structures 208 in the gap region. The PCM region 240 is the region or space in the gap region 209 that is used to incorporate PCM structures 208.

In some examples, the plurality of PCM structures 208 in the PCM region 240 form one or more PCM units 235.1, 235.2, 235.3, 235.4. In some examples, each PCM unit 235.1, 235.2, 235.3, 235.4 may include ten or more PCM structures 208. In some examples, each PCM unit 235.1, 235.2, 235.3, 235.4 may include fourteen or more PCM structures 208. In some examples, each PCM unit 235.1, 235.2, 235.3, 235.4 may include seventeen or more PCM structures 208.

In some examples, each PCM unit 235.1, 235.2, 235.3, 235.4 is a set of PCM structures 208 in the PCM region 240 located between two scribe lines 232 that are generally perpendicular to the super street 205. For instance, each PCM unit 235.1, 235.2, 235.3, 235.4 may be the set of PCM structures 208 in the PCM region 240 between the first scribe line 210, the second scribe line 212, and two of the horizontal scribe lines 232.

In the example of FIG. 5, the device array 230 includes four PCM units 235.1, 235.2, 235.3, 235.4. Each PCM unit 235.1, 235.2, 235.3, 235.4 may include the same set of PCM structures 208 or a different set of PCM structures 208. Each PCM unit 235.1, 235.2, 235.3, 235.4 may be the same size or a different size.

Each PCM unit 235.1, 235.2, 235.3, 235.4 has an associated PCM unit area. The PCM unit area is the space taken up in the PCM region 240 by the PCM unit 235.1, 235.2, 235.3, 235.4.

As shown in FIG. 5, each PCM unit 235.1, 235.2, 235.3, 235.4 has an associated area defined by the length L_{PCM3} and the W_{PCM3} of the PCM region 240. The width W_{PCM3} may correspond to the width of the gap region 209 in some embodiments. The length L_{PCM3} may be the length between horizontal scribe lines 232 in some embodiments.

The PCM area for each PCM unit 235.1, 235.2, 235.3, 235.4 may be less than an area of one of the plurality of device structures 204 in the device array 230. A device structure 204 may have an area defined by device length L_{D3} and device width W_{D3}. The PCM area for each PCM unit 235.1, 235.2, 235.3, and 235.4 defined by L_{PCM3} and W_{PCM3} may be less than the area of the device structure 204 defined by the device width W_{D3} and the device length L_{D3}.

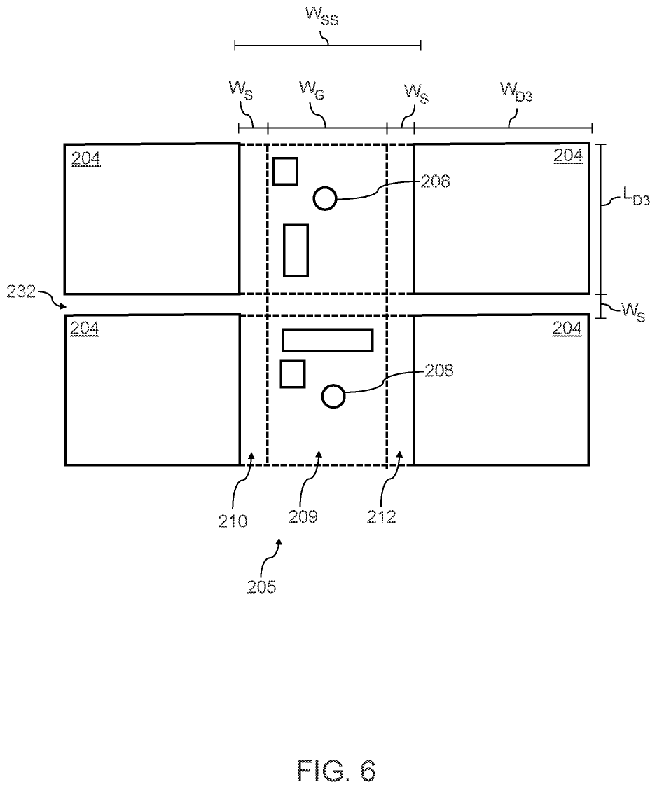

In some examples, the PCM structures 208 may be positioned in the gap region 209 such that the PCM structures 208 do not overlap any scribe lines. For instance, FIG. 6 depicts a close-up view of a superstreet region 205 between semiconductor device structures 204. As shown in FIG. 6, the superstreet region 205 includes a first scribe line 210 having a width W_{S}, a second scribe line 212 having a width W_{S}, and a gap region 209 between the first scribe line 210 and the second scribe line 212. The gap region 209 may have a width W_{G}.

A third scribe line 232 runs in a generally perpendicular direction to the first scribe line 210 and the second scribe line 212. The third scribe line 232 may have a width W_{S}. The third scribe line 232 may cross the gap region 209. The PCM structures 208 are located within the gap region 209 so that there is no overlap with the first scribe line 210, the second scribe line 212, or the third scribe line 232.

As shown in FIG. 6, the gap region 209 may have a width W_{G}. The width W_{G} of the gap region 209 is greater than the width W_{S} of the scribe lines 210, 210, 232. The width W_{G} of the gap region 209 is less than the device width W_{D3} of the semiconductor device structure 204.

The superstreet region 205 may have a width W_{SS}. The width W_{SS} of the superstreet region 205 may be the sum of the width W_{S} of the first scribe line 210, the width W_{S} of the second scribe line 212, and the width W_{G} of the gap region 209. The width W_{SS} of the superstreet region 205 is less than a device width W_{D3} of the semiconductor device structure 204, such as five times less than the device width W_{D3} of the semiconductor device structure 204, such as ten times less than the device width W_{D3} of the semiconductor device structure 204. In some embodiments, the width W_{SS} of the superstreet region 205 may be in a range of 400 microns to about 1200 microns, such as about 400 microns to about 700 microns, such as about 700 microns to about 1000 microns, such as about 500 microns to about 650 microns, such as about 800 microns to about 1000 microns, such as any other range between 400 microns and 1200 microns.

The use of superstreet regions 205 for PCM structures 208 as discussed with reference to FIGS. 3-6 allows for the incorporation of PCM structures 208 throughout the surface of the semiconductor wafer 200 while reducing the total area occupied by the PCM structures 208, leaving more room for semiconductor device structures 204 and increasing semiconductor wafer yield.

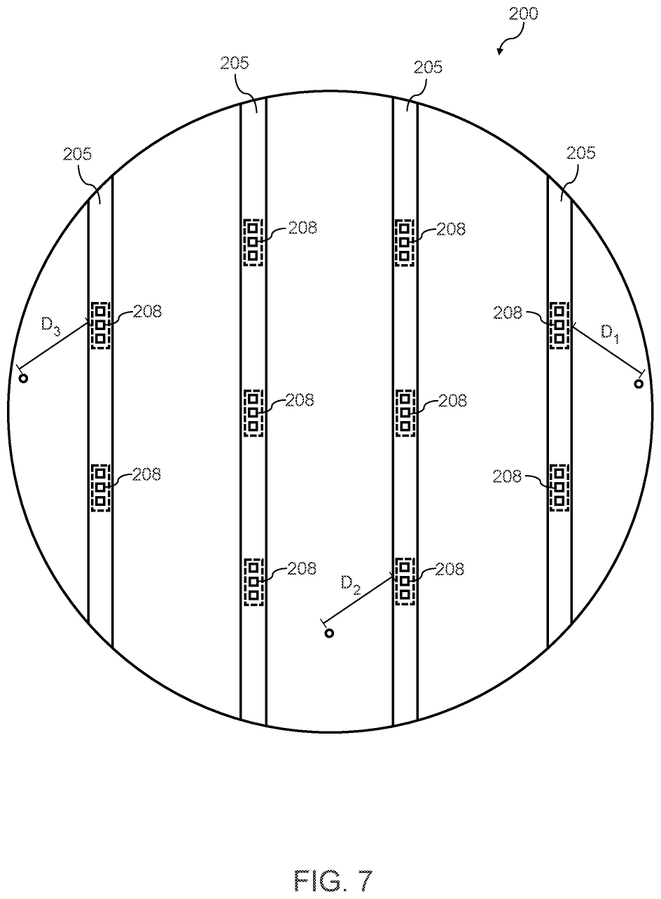

For instance, FIG. 7 depicts a simplified view of a semiconductor wafer 200 having a plurality of superstreet regions 205 according to examples of the present disclosures. The semiconductor device structures 204 are not illustrated on the semiconductor wafer 200 for purposes of illustration and discussion. The semiconductor wafer 200 may have a plurality of PCM structures 208 in the superstreet regions 205. As discussed above, the semiconductor wafer 200 may be a silicon carbide-based semiconductor wafer.

The plurality of PCM structures 208 are distributed throughout the semiconductor wafer such that every device structure on the semiconductor wafer is within about 20 mm or less of a PCM structure 208. For instance, example distances D1, D2, and D3 between semiconductor device structures and a PCM structure 208 are illustrated in FIG. 7. Each of the distances D1, D2, and D3 may be about 20 mm or less. By distributing PCM structures 208 in this manner, the PCM data obtained from testing the PCM structures 208 may be associated with all device structures on the semiconductor wafer 200.

In addition, although a sufficient number of PCM structures 208 are distributed on the semiconductor wafer 200 such that each semiconductor device structure on the semiconductor wafer 200 is within about 20 mm or less of a PCM structure 208, the total process control monitor area of all the PCM structures 208 on the semiconductor wafer is less than about 3% of the surface area of the semiconductor wafer 200, such as less than about 2% of the surface area of the semiconductor wafer, such as in a range of about 0.5% to about 3%, such as in a range of about 1% to about 2%. The total process control monitor area is defined as the aggregate surface area on the semiconductor wafer taken up by all of the PCM structures on the semiconductor wafer.

In some examples, the semiconductor wafer may have a utilization area that is indicative of the total area on the semiconductor wafer that is used for semiconductor device structures (e.g., eventual semiconductor die). In some examples, the utilization area is about 90% or greater of a surface area of the semiconductor wafer, such as about 95% or greater.

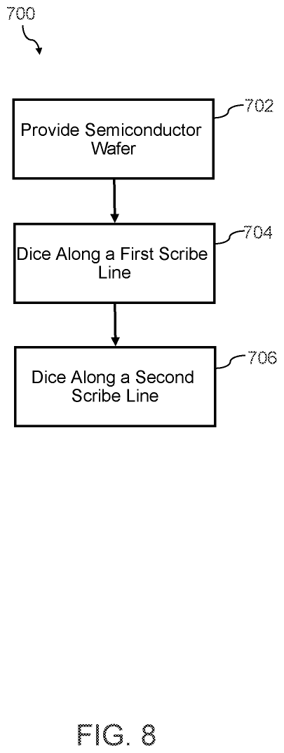

FIG. 8 depicts a flow chart of an example method 700 for fabricating a semiconductor wafer according to example embodiments of the present disclosure. FIG. 8 depicts example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 702, the method 700 may include providing a semiconductor wafer having a substrate, such as silicon carbide substrate. The semiconductor wafer may be the semiconductor wafer 200 described with reference to FIGS. 2-7. In some examples, the semiconductor wafer may include a plurality of device structures (e.g., semiconductor die) on the substrate, such as a first device structure and a second device structure. The semiconductor wafer may include a gap region on the substrate between the first device structure and the second device structure. The gap region may be between scribe lines on the semiconductor wafer, such as a first scribe line and a second scribe line. The semiconductor wafer may include one or more PCM structures on the gap region.

In some examples, the gap region is a linear gap region that is generally parallel to one or more scribe lines on the semiconductor wafer. The gap region may not intersect any device structure on the substrate. The PCM structures may be in the gap region such that no scribe line intersects the one or more PCM structures. The PCM structures may form one or more PCM units. Each PCM unit may include, for instance, ten or more PCM structures, such as fourteen or more PCM structures, such as seventeen or more PCM structures. In some examples, as discussed with reference to FIG. 5, the PCM area associated with the PCM unit is less than a device area associated with a device structure.

At 704, the method 700 includes dicing the semiconductor wafer along a first scribe line on a first side of the gap region. Any suitable cutting instrument can be used to make a cut along the first scribe line. Suitable cutting instruments can include saws, lasers, etc. In some embodiments, the PCM structures do not overlap or intersect any scribe line on the semiconductor wafer. In this regard, dicing the semiconductor wafer along the first scribe line does not cut any PCM structures on the semiconductor wafer.

At 706, the method 700 includes dicing the semiconductor wafer along a second scribe line on a second side of the gap region. Any suitable cutting instrument can be used to make a cut along the first scribe line. Suitable cutting instruments can include saws, lasers, etc. In some embodiments, the PCM structures do not overlap or intersect any scribe line on the semiconductor wafer. In this regard, dicing the semiconductor wafer along the second scribe line does not cut any PCM structures on the semiconductor wafer.

Table 1 below shows example yield gains for a 150 mm silicon carbide semiconductor wafer having a PCM unit per device array corresponding to a reticle (e.g., as shown in FIG. 1) versus a semiconductor wafer having PCM structures in superstreets according to examples of the present disclosure (e.g., as shown in FIG. 3). The % yield gain represents the percentage of additional semiconductor device structures that may be incorporated onto a semiconductor wafer having superstreets according to examples of the present disclosure.

TABLE 1
150 mm Semiconductor Wafer

| Device Structure | % Yield Gain for | % Yield Gain for |
|---|---|---|
| Size (e.g., | 858 micron (width) | 618 micron (width) |
| Die Size) (mm) | Superstreet | Superstreet |
| 5 × 5 | 3.17 | 4.24 |
| 4.9 × 7.7 | 9.94 | 10.47 |

Table 2 below shows example yield gains for a 200 mm silicon carbide semiconductor wafer having a PCM unit per device array corresponding to a reticle (e.g., as shown in FIG. 1) versus a semiconductor wafer having PCM structures in superstreets according to examples of the present disclosure (e.g., as shown in FIG. 3). The % yield gain represents the percentage of additional semiconductor device structures that may be incorporated onto a semiconductor wafer having superstreets according to examples of the present disclosure.

TABLE 2
200 mm Semiconductor Wafer

| Device Structure | % Yield Gain for | % Yield Gain for |
|---|---|---|
| Size (e.g., | 858 micron (width) | 618 micron (width) |
| Die Size) (mm) | Superstreet | Superstreet |
| 5 × 5 | 1.42 | 2.90 |
| 4.9 × 7.7 | 7.48 | 8.91 |

One example aspect of the present disclosure is directed to a semiconductor wafer. The semiconductor wafer includes a substrate. The semiconductor wafer further includes a first device structure on the substrate. The semiconductor wafer further includes a second device structure on the substrate. The semiconductor wafer further includes a gap region on the substrate between the first device structure and the second device structure. The semiconductor wafer further includes one or more process control monitor structures in the gap region. The semiconductor wafer further includes a first scribe line on a first side of the gap region and a second scribe line on a second side of the gap region.

In some examples, the substrate comprises silicon carbide.

In some examples, the gap region does not intersect any device structure on the substrate.

In some examples, the semiconductor wafer comprises a flat or a notch associated with a crystal orientation of the semiconductor wafer.

In some examples, the gap region is generally perpendicular to the flat or the notch.

In some examples, the gap region is generally parallel to the flat or the notch.

In some examples, the one or more process control monitor structures each comprise one or more of a metrology structure, an alignment structure, or an electrical test structure.

In some examples, the first device structure or second device structure comprises a semiconductor die.

In some examples, the semiconductor die comprises a transistor or a diode.

In some examples, the gap region is a linear gap region that is generally parallel to the first scribe line and the second scribe line.

In some examples, the gap region, the first scribe line and the second scribe line define a superstreet region.

In some examples, the superstreet region has a width that is at least five times smaller than a device width of the first device structure.

In some examples, the one or more process control monitor structures comprise ten or more process control monitor structures forming a process control monitor unit.

In some examples, a process control monitor area associated with the process control monitor unit is less than a device area associated with the device structure.

Another example aspect of the present disclosure is directed to a method for processing a semiconductor wafer. The method includes providing a semiconductor wafer comprising a substrate, a first device structure on the substrate, a second device structure on the substrate, a gap region on the substrate between the first device structure and the second device structure, and one or more process control monitor structures on the gap region. The method further includes dicing the semiconductor wafer along a first scribe line on a first side of the gap region. The method further includes dicing the semiconductor wafer along a second scribe line on a second side of the gap region.

In some examples, the substrate comprises silicon carbide.

In some examples, the gap region does not intersect any device structure on the substrate.

In some examples, the gap region is a linear gap region that is generally parallel to the first scribe line and the second scribe line.

In some examples, no scribe line intersects the one or more process control monitor structures.

In some examples, the one or more process control monitor structures each comprise one or more of a metrology structure, an alignment structure, or an electrical test structure.

In some examples, the first device structure and the second device structure comprise a semiconductor die.

In some examples, the gap region, the first scribe line, and the second scribe line define a superstreet region, the superstreet region having a width that is smaller than a device width of the first device structure.

In some examples, the superstreet region has a width that is at least five times smaller than a device width of the first device structure.

In some examples, the one or more process control monitor structures comprise ten or more process control monitor structures forming a process control monitor unit.

In some examples, a process control monitor area associated with the process control monitor unit is less than a device area associated with the device structure.

Another example aspect of the present disclosure is directed to a semiconductor wafer. The semiconductor wafer includes a substrate. The semiconductor wafer further includes a plurality of semiconductor device structures on the substrate divided by a plurality of scribe lines for separating the semiconductor device structures. The semiconductor wafer further includes a gap region extending between a plurality of the semiconductor devices, the gap region having a width that is greater than one of the scribe lines and less than the width of one of the semiconductor device structures. The semiconductor wafer further includes at least one process control monitor structure within the gap region.

In some examples, the substrate comprises silicon carbide.

In some examples, the gap region does not intersect any device structure on the substrate.

In some examples, the gap region is a linear gap region that is generally parallel to one of the plurality of scribe lines.

In some examples, the at least one process control monitor structure is a metrology structure, an alignment structure, or an electrical test structure.

Another example aspect of the present disclosure is directed to a semiconductor wafer. The semiconductor wafer includes a substrate. The semiconductor wafer further includes a plurality of device structures on the substrate. Each device array comprises a process control monitor unit has one or more process control monitor structures. An area of the process control monitor unit is less than an area of one of the plurality of device structures.

In some examples, the plurality of device structures are arranged in one or more device arrays.

In some examples, the substrate comprises silicon carbide.

In some examples, the one or more process control monitor structures each comprise one or more of a metrology structure, an alignment structure, or an electrical test structure.

In some examples, the process control monitor unit comprises at least ten process control monitor structures.

In some examples, the process control monitor unit comprises at least fourteen process control monitor structures.

In some examples, the utilization area for semiconductor devices on the semiconductor wafer is greater than about 90%.

In some examples, the process control monitor unit is in a gap region defined between a first scribe line and a second scribe line on the semiconductor wafer.

In some examples, the gap region is a linear gap region having a length generally parallel to the first scribe line and the second scribe line.

Another example aspect of the present disclosure is directed to a semiconductor wafer. The semiconductor wafer includes a substrate. The semiconductor wafer further includes a plurality of device structures on the substrate. The semiconductor wafer further includes a plurality of process control monitor structures on the substrate, the plurality of process control monitor structures distributed on the substrate such that all of the plurality of device structures on the substrate are within about 20 mm of at least one of the plurality of process control monitor structures. A total process control monitor area occupied by all the process monitor control structures is less than about 3% of a surface area of the semiconductor wafer.

In some examples, the substrate comprises silicon carbide.

In some examples, one or more of the plurality of process control monitor structures is in a gap region located between a first device structure and a second device structure on the substrate.

In some examples, the gap region does not intersect any device structure on the substrate.

In some examples, the gap region is a linear gap region.

In some examples, the plurality of process control monitor structures each comprise one or more of a metrology structure, an alignment structure, or an electrical test structure.

In some examples, the plurality of device structures each comprise a semiconductor die.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor wafer, comprising:
a substrate;
a first device structure on the substrate;
a second device structure on the substrate;
a gap region on the substrate between the first device structure and the second device structure;
one or more process control monitor structures in the gap region; and
a first scribe line on a first side of the gap region and a second scribe line on a second side of the gap region.

2. The semiconductor wafer of claim 1, wherein the substrate comprises silicon carbide.

3. The semiconductor wafer of claim 1, wherein the gap region does not intersect any device structure on the substrate.

4. The semiconductor wafer of claim 1, wherein the semiconductor wafer comprises a flat or a notch associated with a crystal orientation of the semiconductor wafer.

5. The semiconductor wafer of claim 4, wherein the gap region is generally perpendicular to the flat or the notch.

6. The semiconductor wafer of claim 4, wherein the gap region is generally parallel to the flat or the notch.

7. The semiconductor wafer of claim 1, wherein the one or more process control monitor structures each comprise one or more of a metrology structure, an alignment structure, or an electrical test structure.

8. The semiconductor wafer of claim 1, wherein the first device structure or second device structure comprises a semiconductor die.

9. The semiconductor wafer of claim 8, wherein the semiconductor die comprises a transistor or a diode.

10. The semiconductor wafer of claim 1, wherein the gap region is a linear gap region that is generally parallel to the first scribe line and the second scribe line.

11. The semiconductor wafer of claim 1, wherein the gap region, the first scribe line and the second scribe line define a superstreet region.

12. The semiconductor wafer of claim 11, wherein the superstreet region has a width that is at least five times smaller than a device width of the first device structure.

13. The semiconductor wafer of claim 1, wherein the one or more process control monitor structures comprise ten or more process control monitor structures forming a process control monitor unit.

14. The semiconductor wafer of claim 13, wherein a process control monitor area associated with the process control monitor unit is less than a device area associated with the device structure.

15. A method for processing a semiconductor wafer, the method comprising:
providing a semiconductor wafer comprising a substrate, a first device structure on the substrate, a second device structure on the substrate, a gap region on the substrate between the first device structure and the second device structure, and one or more process control monitor structures on the gap region;
dicing the semiconductor wafer along a first scribe line on a first side of the gap region; and
dicing the semiconductor wafer along a second scribe line on a second side of the gap region.

16.-18. (canceled)

19. The method of claim 15, wherein no scribe line intersects the one or more process control monitor structures.

20.-39. (canceled)

40. A semiconductor wafer, comprising:
a substrate;
a plurality of device structures on the substrate;
a plurality of process control monitor structures on the substrate, the plurality of process control monitor structures distributed on the substrate such that all of the plurality of device structures on the substrate are within about 20 mm of at least one of the plurality of process control monitor structures; and
wherein a total process control monitor area occupied by all the process monitor control structures is less than about 3% of a surface area of the semiconductor wafer.

41. The semiconductor wafer of claim 40, wherein the substrate comprises silicon carbide.

42. The semiconductor wafer of claim 40, wherein one or more of the plurality of process control monitor structures is in a gap region located between a first device structure and a second device structure on the substrate.

43. The semiconductor wafer of claim 42, wherein the gap region does not intersect any device structure on the substrate.

44.-46. (canceled)
